(19) United States
(12) Patent Application Publication
(10) Pub. No.: US 2021/0036490 A1
(43) Pub. Date: Feb. 4, 2021

(54) SURFACE-EMITTING LASER AND METHOD FOR MANUFACTURING THE SAME

(71) Applicant: SUMITOMO ELECTRIC INDUSTRIES, LTD., Osaka (JP)

(72) Inventor: Tetsuya KUMANO, Osaka-shi (JP)

(73) Assignee: SUMITOMO ELECTRIC INDUSTRIES, LTD., Osaka (JP)

(21) Appl. No.: 16/922,336

(22) Filed: Jul. 7, 2020

(30) Foreign Application Priority Data
Jul. 29, 2019 (JP) 2019-139138

(51) Int. Cl. H01S 5/183

(52) U.S. Cl. CPC H01S 5/18347; H01S 5/18313

(57) ABSTRACT

A surface-emitting laser includes a substrate, a lower reflector layer disposed on the substrate, an active layer disposed on the lower reflector layer, and an upper reflector layer disposed on the active layer. The lower reflector layer, the active layer, and the upper reflector layer form a mesa. The mesa has a current confinement structure. The current confinement structure includes a current confinement layer. The current confinement layer includes an oxide layer extending from a periphery of the mesa and an aperture surrounded by the oxide layer. The aperture overlaps the active layer. The aperture has a major axis and a minor axis. A length of the major axis is twice or more a length of the minor axis.

### CROSS-REFERENCE TO RELATED APPLICATION

This application is based upon and claims the benefit of priority of the prior Japanese Patent Application No. 2019-139138, filed on Jul. 29, 2019, the entire contents of which are incorporated herein by reference.

### BACKGROUND OF THE INVENTION

### 1. Field of the Invention

The present invention relates to surface-emitting lasers and methods for manufacturing surface-emitting lasers.

### 2. Description of the Related Art

Vertical-cavity surface-emitting lasers (VCSELs, which may be simply referred to as “surface-emitting laser”) include two reflector layers and an active layer sandwiched between the reflector layers. To achieve current confinement, a portion of one reflector layer is selectively oxidized to form an oxide current confinement layer (see, for example, Japanese Unexamined Patent Application Publication No. 2007-251174).

### SUMMARY OF THE DISCLOSURE

VCSELs generate heat during operation because carrier recombination occurs in the active layer which includes a p-n junction. The active layer is sandwiched between the reflector layers, which have a higher thermal resistance than, for example, the substrate. Thus, VCSELs have a lower heat dissipation performance than other laser devices and are therefore more susceptible to thermal degradation. Accordingly, an object of the present disclosure is to provide a surface-emitting laser with a reduced susceptibility to thermal degradation and a method for manufacturing such a surface-emitting laser.

A surface-emitting laser according to one aspect of the present disclosure includes a substrate, a lower reflector layer disposed on the substrate, an active layer disposed on the lower reflector layer, and an upper reflector layer disposed on the active layer. The lower reflector layer, the active layer, and the upper reflector layer form a mesa. The mesa has a current confinement structure. The current confinement structure includes a current confinement layer. The current confinement layer includes an oxide layer extending from the periphery of the mesa and an aperture surrounded by the oxide layer. The aperture overlaps the active layer. The aperture has a major axis and a minor axis. The length of the major axis is twice or more the length of the minor axis.

A method for manufacturing a surface-emitting laser according to another aspect of the present disclosure includes the steps of forming, in sequence, a lower reflector layer, an active layer, and an upper reflector layer on a substrate; forming a mesa from the lower reflector layer, the active layer, and the upper reflector layer; and forming a current confinement structure in the mesa. The step of forming the current confinement structure includes oxidizing a portion of the upper reflector layer from the periphery of the mesa to form an oxide layer and an aperture surrounded by the oxide layer. The aperture overlaps the active layer. The mesa has a major axis and a minor axis. The length of the major axis of the mesa is twice or more the length of the minor axis of the mesa. The lower reflector layer, the active layer, and the upper reflector layer are formed on the (100) plane of the substrate.

### BRIEF DESCRIPTION OF THE DRAWINGS

FIG. 1A is a plan view showing an example surface-emitting laser according to a first embodiment.

FIG. 1B is a sectional view showing the example surface-emitting laser.

FIGS. 2A and 2B are plan views showing a mesa and an aperture.

FIGS. 3A and 3B are sectional views showing an example method for manufacturing the surface-emitting laser.

FIGS. 4A and 4B are sectional views showing the example method for manufacturing the surface-emitting laser.

FIGS. 5A and 5B are sectional views showing the example method for manufacturing the surface-emitting laser.

FIG. 6A is a graph showing a relationship between thermal resistance and life.

FIG. 6B is a graph showing a relationship between aspect ratio and thermal resistance.

FIG. 6C is a graph showing a relationship between aspect ratio and life.

FIG. 7 is a schematic view showing an example heat path.

FIG. 8 is a plan view showing a mesa and an aperture.

### DESCRIPTION OF THE PREFERRED EMBODIMENTS

### Description of Embodiments of the Disclosure

First, embodiments of the present disclosure will be listed and described.

(1) One embodiment of the present disclosure is a surface-emitting laser including a substrate, a lower reflector layer disposed on the substrate, an active layer disposed on the lower reflector layer, and an upper reflector layer disposed on the active layer. The lower reflector layer, the active layer, and the upper reflector layer form a mesa. The mesa has a current confinement structure. The current confinement structure includes a current confinement layer. The current confinement layer includes an oxide layer extending from the periphery of the mesa and an aperture surrounded by the oxide layer. The aperture overlaps the active layer. The aperture has a major axis and a minor axis. The length of the major axis is twice or more the length of the minor axis. This increases the cross-sectional area of a heat path formed under the aperture and thus decreases the thermal resistance. As a result, the susceptibility of the surface-emitting laser to thermal degradation is reduced.

(2) The length of the major axis of the aperture may be twice or more and ten times or less the length of the minor axis of the aperture. This decreases the thermal resistance without significantly increasing the aspect ratio of laser light.

(3) The aperture may be elliptical. Because such an aperture has an aspect ratio of greater than 1:1, the thermal resistance decreases, thus reducing the susceptibility to thermal degradation.

(4) The mesa may have a major axis and a minor axis, and the length of the major axis of the mesa may be twice or more the length of the minor axis of the mesa. By performing oxidation from the periphery toward the inside of such a mesa, an aperture having a major axis and a minor axis can be formed.

(5) The lower reflector layer, the active layer, and the upper reflector layer may be disposed on the (100) plane of the substrate, and the major axis of the mesa may be inclined with respect to the <011> direction of the substrate. The oxidation speed of the upper reflector layer is dependent on plane orientation. If the major axis is inclined, the effect of the difference in oxidation speed is reduced, and therefore, an aperture of the target shape can be formed.

(6) The major axis of the mesa may be inclined at an angle of 35° or more and 55° or less with respect to the <011> direction of the substrate. If the major axis is inclined with respect to the <011> direction, in which the oxidation speed is slower, the effect of the difference in the oxidation speed of the upper reflector layer is reduced, and therefore, an aperture of the target shape can be formed.

(7) The substrate may be formed of gallium arsenide. The lower reflector layer and the upper reflector layer may be formed of aluminum gallium arsenide. The current confinement layer may include aluminum oxide. Whereas gallium arsenide has a lower thermal resistance, aluminum gallium arsenide has a higher thermal resistance. The active layer, which generates heat, is sandwiched between the aluminum gallium arsenide upper and lower reflector layers. If the aspect ratio of the aperture is increased, the thermal resistance decreases, and heat is released through the heat path under the aperture and the substrate.

(8) Another embodiment of the present disclosure is a method for manufacturing a surface-emitting laser, including the steps of forming, in sequence, a lower reflector layer, an active layer, and an upper reflector layer on a substrate; forming a mesa from the lower reflector layer, the active layer, and the upper reflector layer; and forming a current confinement structure in the mesa. The step of forming the current confinement structure includes oxidizing a portion of the upper reflector layer from the periphery of the mesa to form an oxide layer and an aperture surrounded by the oxide layer. The aperture overlaps the active layer. The mesa has a major axis and a minor axis. The length of the major axis of the mesa is twice or more the length of the minor axis of the mesa. The lower reflector layer, the active layer, and the upper reflector layer are formed on the (100) plane of the substrate. Because of a difference in oxidation speed, an aperture having a major axis and a minor axis can be formed. This increases the cross-sectional area of a heat path formed under the aperture and thus decreases the thermal resistance. As a result, the susceptibility of the surface-emitting laser to thermal degradation is reduced.

### DETAILS OF EMBODIMENTS OF THE DISCLOSURE

Specific examples of surface-emitting lasers and methods for manufacturing surface-emitting lasers according to embodiments of the present disclosure will hereinafter be described with reference to the drawings. It should be understood, however, that the invention is not limited to these examples, but is indicated by the claims, and all changes that come within the meaning and range of equivalency of the claims are intended to be embraced therein.

### First Embodiment

### Surface-Emitting Laser

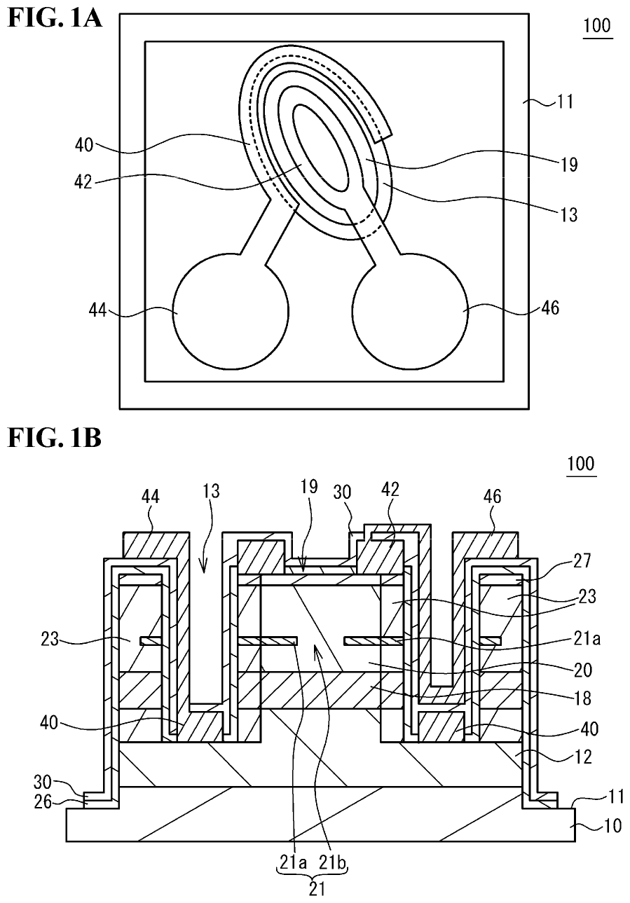

FIG. 1A is a plan view showing an example surface-emitting laser 100 according to a first embodiment, and FIG. 1B is a sectional view showing the example surface-emitting laser 100.

As shown in FIG. 1A, a groove 11 for device isolation is formed on the outer periphery of the surface-emitting laser 100. A mesa 19 and pads 44 and 46 are located within the portion surrounded by the groove 11. A groove 13 is formed around the mesa 19. An electrode 42 is disposed on the mesa 19, whereas an electrode 40 is disposed in the groove 13. The pad 44 is electrically connected to the electrode 40, whereas the pad 46 is electrically connected to the electrode 42. The length of each side of the surface-emitting laser 100 is, for example, 300 μm.

As shown in FIG. 1B, the surface-emitting laser 100 is a VCSEL including a substrate 10, distributed Bragg reflector (DBR) layers 12 and 20, a contact layer 27, and an active layer 18.

The substrate 10 is, for example, a semiconductor substrate formed of semi-insulating gallium arsenide (GaAs). For example, the DBR layer 12 (lower reflector layer), the active layer 18, the DBR layer 20 (upper reflector layer), and the contact layer 27 are disposed in sequence on the (100) plane of the substrate 10. The top surfaces of these layers are parallel to the top surface of the substrate 10. A GaAs or AlGaAs buffer layer may be disposed between the substrate 10 and the DBR layer 12.

Each of the DBR layers 12 and 20 is, for example, a semiconductor multilayer film composed of alternately stacked AlₓGa₁₋ₓAs (where x=0.16) and Al_{y}Ga_{1-y}As (where y=0.9) layers, each having an optical thickness of λ/4. The DBR layer 12 is an n-type semiconductor layer that is, for example, doped with silicon (Si) to a concentration of 5×10¹⁷ cm⁻³ or more and 3×10¹⁸ cm⁻³ or less. The DBR layer 20 is a p-type semiconductor layer that is, for example, doped with zinc (Zn) to a concentration of 1×10¹⁸ cm⁻³ or more and 1×10¹⁹ cm⁻³ or less.

The contact layer 27 is, for example, a p-type AlₓGa₁₋ₓAs (where x=0.16) layer having a thickness of 100 nm and doped with Zn to a concentration of 1×10¹⁹ cm⁻³.

The active layer 18 has, for example, a multiple quantum well (MQW) structure composed of alternately stacked In_{y}Ga_{1-y}As (where y=0.107) and AlₓGa₁₋ₓAs (where x=0.3) layers, and has an optical gain. The substrate 10, the DBR layer 12, the active layer 18, the DBR layer 20, and the contact layer 27 may also be formed of other compound semiconductors.

The DBR layer 12, the active layer 18, the DBR layer 20, and the contact layer 27 form, for example, an elliptical frustoconical or elliptical cylindrical mesa 19. The mesa 19 has a height of, for example, 4.5 μm or more and 5.0 μm or less. The top surface of the mesa 19 has a width of, for example, 30 μm. The top surface of the mesa 19 may be parallel to the top surface of the substrate 10. The side surface of the mesa 19 may be inclined with respect to the stacking direction of the layers. The groove 13 is located around the mesa 19 and has a width of, for example, 20 μm. A high-resistance region 23 is formed on the periphery of the mesa 19.

The DBR layer 20 has a current confinement structure 21. The current confinement structure 21 includes an oxide layer 21a and an aperture 21b. The oxide layer 21a is formed by oxidizing a portion of the plurality of layers included in the DBR layer 20. The oxide layer 21a in the mesa 19 extends from the periphery of the DBR layer 20 and is not formed in the center of the DBR layer 20. The aperture 21b is an unoxidized portion surrounded by the oxide layer 21a and overlaps the active layer 18. The oxide layer 21a includes, for example, aluminum oxide (Al₂O₃). The oxide layer 21a is insulating and thus allows less current to flow therethrough than the unoxidized portion. In contrast, the aperture 21b allows more current to flow therethrough than the oxide layer 21a, thus forming a current path. This current confinement structure 21 permits efficient current injection.

An insulating film 26 is formed of, for example, silicon nitride (SiN) and covers the side and top surfaces of the mesa 19. An insulating film 30 is formed of, for example, SiN and covers the insulating film 26 and the mesa 19. The electrodes 40 and 42 are disposed in openings of the insulating film 30. The electrode 40 is disposed on the top surface of the DBR layer 12, whereas the electrode 42 is disposed on top of the mesa 19, that is, on the top surface of the contact layer 27.

The pads 44 and 46 are disposed on the insulating film 30 and are in contact with the electrodes 40 and 42, respectively. The electrode 42 is formed of, for example, a metal such as a stack of titanium (Ti), platinum (Pt), and gold (Au). The electrode 40 is formed of, for example, a metal such as gold, germanium (Ge), or nickel (Ni). The pads 44 and 46 are formed of, for example, a metal such as Au.

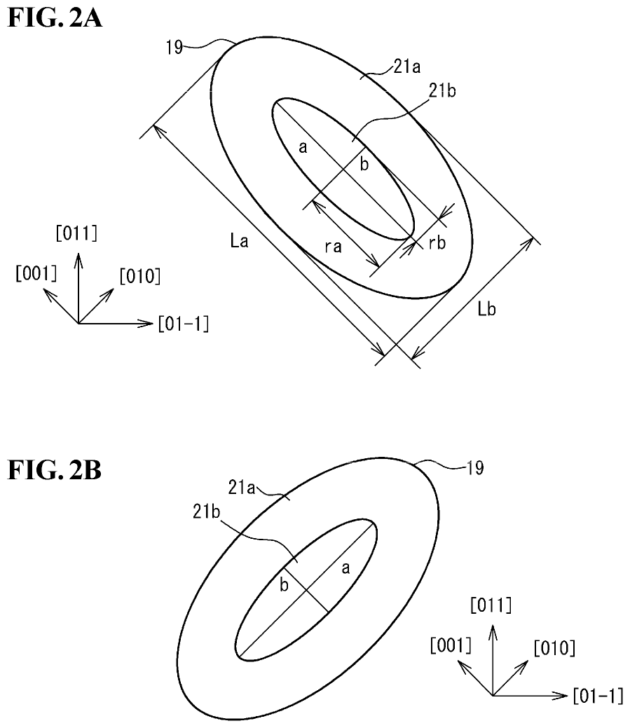

FIGS. 2A and 2B are plan views showing the mesa 19 and the aperture 21b, with other components such as the pads 44 and 46 omitted therefrom. As shown in FIG. 2A and FIG. 2B, the mesa 19 and the aperture 21b have, for example, an elliptical planar shape, each having a major axis and a minor axis. The major axis a of the aperture 21b is the longest straight line extending across the aperture 21b. The minor axis b is a straight line shorter than the major axis a and orthogonal to the major axis a. The major and minor axes of the mesa 19 are similarly defined.

In the example in FIG. 2A, the major and minor axes of the mesa 19 and the aperture 21b are inclined with respect to the [011] and [01-1] directions of the substrate 10. The angle of inclination is, for example, in the range of 35° or more and 55° or less, for example, 45°. The major axis a of the aperture 21b is oriented in the [001] direction, whereas the minor axis b of the aperture 21b is oriented in the [010] direction. The major and minor axes of the mesa 19 are oriented in the same direction as those of the aperture 21b.

The length La of the major axis of the mesa 19 is greater than the length 2ra of the major axis a of the aperture 21b, whereas the length Lb of the minor axis of the mesa 19 is greater than the length 2rb of the minor axis b of the aperture 21b. Here, the aspect ratio is defined as the ratio of the major radius to the minor radius. The aspect ratio of the aperture 21b (the ratio of the major radius ra to the minor radius rb) is, for example, 2:1 or more and 10:1 or less, meaning that the length 2ra of the major axis a is twice or more and ten times or less the length 2rb of the minor axis b. The aspect ratio of the mesa 19 is also 2:1 or more and 10:1 or less, meaning that the length La of the major axis is twice or more and ten times or less the length Lb of the minor axis.

As described later, the oxide layer 21a is formed by oxidizing a portion of the DBR layer 20, and the unoxidized portion serves as the aperture 21b. Thus, the shape and size of the aperture 21b can be controlled by oxidation during the formation of the oxide layer 21a. The oxidation speed of the DBR layer 20 is dependent on plane orientation: it is slower in the [011] and [01-1] directions and is faster in the [001] and [010] directions. As shown in FIG. 2A, the elliptical aperture 21b can be formed if the major axis of the mesa 19 is oriented in the [001] direction, the minor axis of the mesa 19 is oriented in the [010] direction, and oxidation is performed from the periphery of the mesa 19.

In the example in FIG. 2B, the mesa 19 and the aperture 21b are oriented in a direction 90° from that of the example in FIG. 2A. That is, the major axis is oriented in the direction, whereas the minor axis is oriented in the [001] direction. Although the mesa 19 and the aperture 21b in the first embodiment may be oriented as in either FIG. 2A or 2B, the example in FIG. 2A will be described below.

### Method of Manufacture

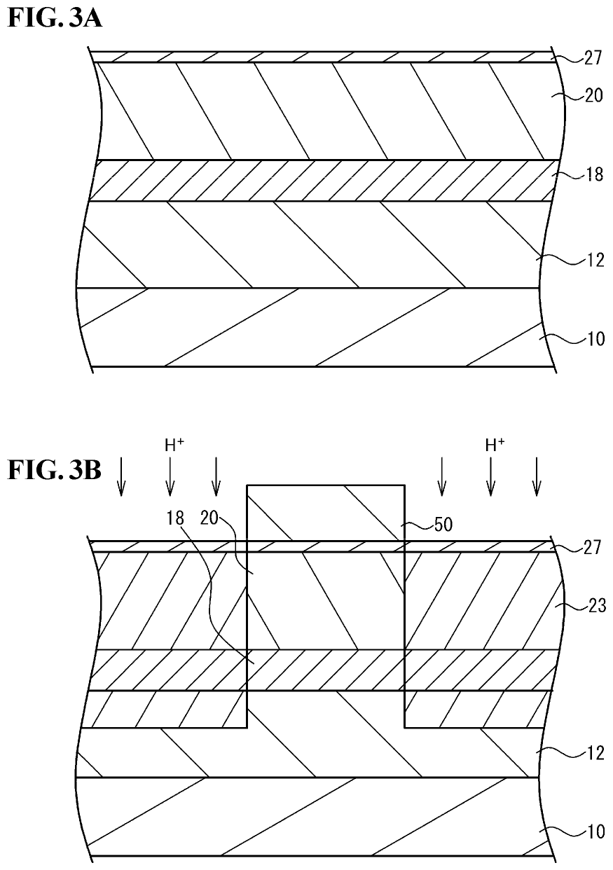

FIGS. 3A to 5B are sectional views showing an example method for manufacturing the surface-emitting laser 100. As shown in FIG. 3A, the DBR layer 12, the active layer 18, the DBR layer 20, and the contact layer 27 are epitaxially grown in sequence on the substrate 10 in wafer form, for example, by metal-organic chemical vapor deposition (MOCVD) or molecular beam epitaxy (MBE). These layers are grown on the (100) plane of the substrate 10. The DBR layer 20 includes an AlₓGa₁₋ₓAs layer (where 0.9≤x≤1.0) for the formation of the oxide layer 21a.

As shown in FIG. 3B, a mask 50 is formed on the contact layer 27, and the high-resistance region 23 is formed by implantation of ions such as protons (H⁺). The depth of implantation of the ions is, for example, 3 μm or more and 4.5 μm or less. No ions are implanted into the portion covered by the mask 50.

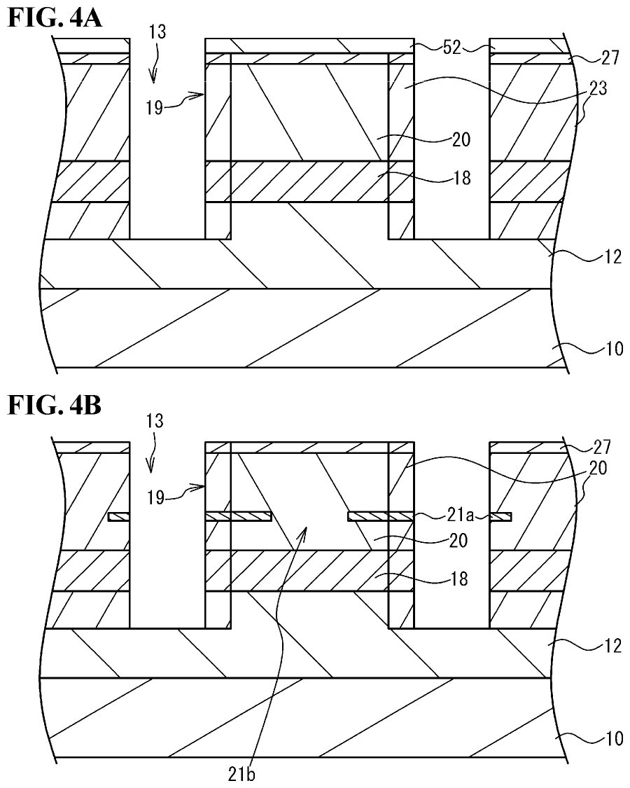

As shown in FIG. 4A, after the mask 50 is removed, a mask 52 is formed. The mask 52 is larger than the mask 50, is elliptical, and covers the region not implanted with ions and a portion of the high-resistance region 23. The mesa 19 is formed, for example, by dry etching with an inductively-coupled-plasma reactive ion etching (ICP-RIE) system. During this process, the groove 13 is formed around the mesa 19. As shown in FIG. 2A, the mesa 19 is, for example, elliptical, with the major axis oriented in the [001] direction and the minor axis oriented in the [010] direction.

As shown in FIG. 4B, the oxide layer 21a is formed by oxidizing the AlₓGa₁₋ₓAs layer (where 0.9≤x≤1.0) of the DBR layer 20 from the periphery thereof, for example, by heating to about 420° C. in a steam atmosphere. The heating time is set so that the oxide layer 21a has a predetermined width, and an unoxidized portion having a predetermined width, that is, the aperture 21b, remains inside the oxide layer 21a. The oxidation speed of the DBR layer 20 is dependent on plane orientation: it is slower in the [011] and [01-1] directions and is faster in the [001] and [010] directions. By performing oxidation from the periphery of the mesa 19, the elliptical aperture 21b shown in FIG. 2A can be formed. The major axis a of the aperture 21b is oriented in the [001] direction, whereas the minor axis b of the aperture 21b is oriented in the [010] direction.

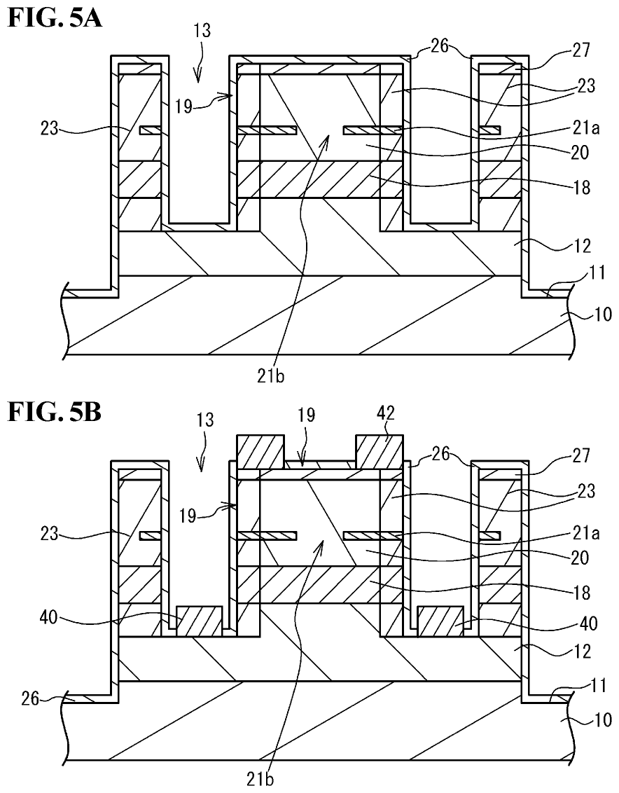

As shown in FIG. 5A, the groove 11 for device isolation is formed to a depth of, for example, 8 μm by dry etching from the DBR layer 12 to the substrate 10. After the groove 11 is formed, an insulating film 26 is formed, for example, by plasma-enhanced CVD.

As shown in FIG. 5B, openings are formed in portions of the insulating film 26 that are located over the mesa 19 and within the groove 13. For example, by resist patterning and vacuum evaporation, the electrode 42 is formed on the contact layer 27, and the electrode 40 is formed on the DBR layer 12. The insulating film 30 is formed on the insulating film 26 and the electrodes 40 and 42, for example, by plasma-enhanced CVD. Openings are formed in portions of the insulating film 30 that overlap the electrodes 40 and 42.

The pads 44 and 46 are formed on the insulating film 30, for example, by plating. The pad 44 is electrically connected to the electrode 40, whereas the pad 46 is electrically connected to the electrode 42. A chip of the surface-emitting laser 100 is formed, for example, by dicing the wafer along the groove 11.

### Thermal Resistance

Next, thermal resistance is described. The surface-emitting laser 100 emits laser light from inside the electrode 40 when a current is injected into the mesa 19 through the pads 44 and 46. The surface-emitting laser 100 generates heat during operation. The active layer 18 includes a p-n junction and thus generates a larger amount of heat than other layers due to carrier recombination.

In general, semiconductor laser devices generate heat, and their emission performance decreases with increasing temperature. In particular, VCSELs have a lower heat dissipation performance in the horizontal direction than edge-emitting laser devices and also have a lower heat dissipation performance in the vertical direction because the active layer is vertically sandwiched between the DBR layers, which have low thermal conductivity. Thus, VCSELs are more susceptible to thermal degradation.

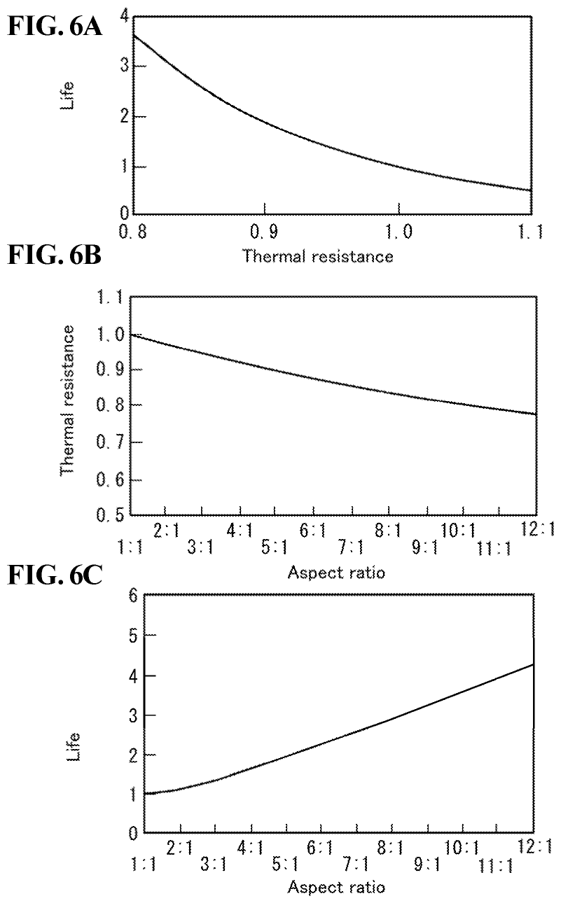

FIG. 6A is a graph showing a relationship between thermal resistance and life. The relationship between thermal resistance and life of a VCSEL was simulated on the assumption that the VCSEL had the same layer structure as that shown in FIG. 1B, and the temperature of the VCSEL was proportional to the product of the thermal resistance and the input energy (1.5 eV). The horizontal axis represents the normalized thermal resistance of the VCSEL, whereas the vertical axis represents the normalized life of the VCSEL. As shown in FIG. 6A, as the thermal resistance becomes higher, the VCSEL degrades faster, and the life becomes shorter. On the other hand, as the thermal resistance decreases, the life becomes longer. For example, if the thermal resistance decreases by 10%, the life doubles. Because the aperture 21b in the first embodiment has an aspect ratio of greater than 1:1, the thermal resistance decreases, thus reducing the susceptibility of the surface-emitting laser 100 to degradation.

### Simulation

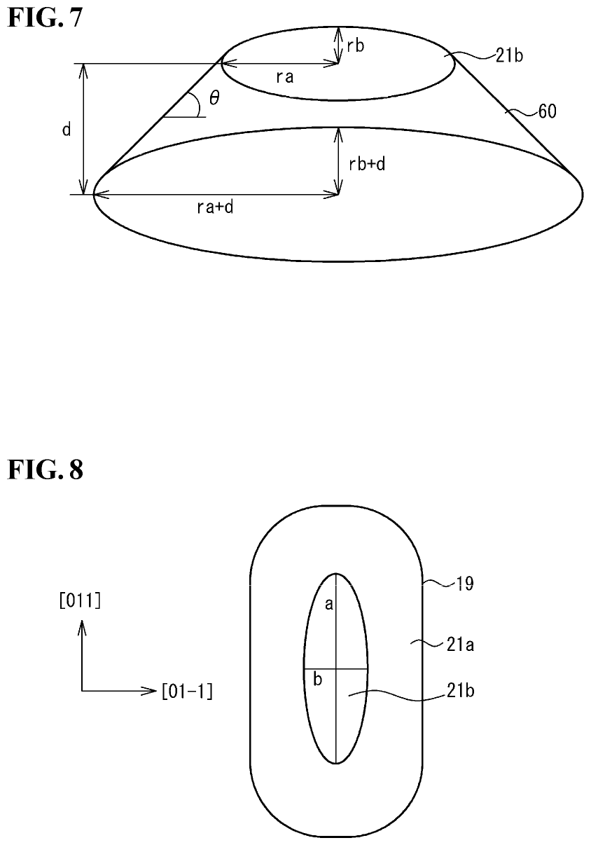

A simulation on thermal resistance and life was performed. FIG. 6B is a graph showing a relationship between aspect ratio and thermal resistance, and FIG. 6C is a graph showing a relationship between aspect ratio and life, both of which are simulation results. The surface-emitting laser 100 shown in FIGS. 1A and 1B was used for calculations for FIGS. 6A and 6B, and a heat path 60 shown in FIG. 7 was assumed in the surface-emitting laser 100.

FIG. 7 is a schematic view showing an example heat path. As shown in FIG. 7, the heat path 60 has an elliptical frustoconical shape extending downward (toward the substrate 10) from the aperture 21b. The top and bottom faces of the heat path 60 are parallel to the main surface of the substrate 10. The angle θ between the bottom and side faces of the heat path 60 is, for example, 45°. Of the layer structure in FIG. 1B, the heat path 60 includes from the DBR layer 20 to the DBR layer 12. The thermal resistance Rth of each layer is calculated by the following equation:

$$Rth = \frac{1}{h} \times \frac{T}{S} \qquad equation 1$$

where h is the thermal conductivity of the layer, T is the thickness of the layer, and S is the cross-sectional area of the layer. The thermal resistance of the entire heat path 60 is the sum of the thermal resistances Rth of the individual layers. It should be noted that the substrate 10 is excluded from the heat path 60. This is because the substrate 10 makes only a minor contribution to the thermal resistance since the substrate 10 is formed of GaAs and thus has a higher thermal conductivity than other layers and also has a large cross-sectional area. Heat traveling through the heat path 60 is released outside through the substrate 10.

The thermal conductivity h shown in equation 1 is determined by the material of the layer. The cross-sectional area S, which is the area of the layer at each depth, becomes larger away from the aperture 21b in the depth direction. The thermal conductivity h and the thickness T do not change with changes in the aspect ratio of the aperture 21b. The cross-sectional area S, on the other hand, changes with the aspect ratio. As can be seen from equation 1, the thermal resistance Rth becomes lower as the cross-sectional area S becomes larger.

For example, it is assumed that the aperture 21b has an aspect ratio of 6.25:1, a major radius ra of 8.75 μm, and a minor radius rb of 1.4 μm. The cross-sectional area of the heat path 60 at the top face (a depth of 0) is equal to the cross-sectional area of the aperture 21b and is expressed by equation 2:

$$\begin{matrix}S = π \times ra \times rb \\ = π \times 12.25\end{matrix} \qquad equation 2$$

The cross-sectional area of the heat path 60 at a depth d is larger than the cross-sectional area at a depth of 0 and is expressed by equation 3:

$$\begin{matrix}S = π \times ( ra + d ) \times ( rb + d ) \\ = π \times ( ra + rb + ( ra + rb ) d + {d}^{2} ) \\ = π \times ( 12.25 + 9.65 d + {d}^{2} )\end{matrix} \qquad equation 3$$

The cross-sectional area of an aperture having an aspect ratio of 1:1, that is, an aperture having a perfect circular shape, at a depth of 0 is expressed by equation 4:

$$\begin{matrix}S = π \times {r}^{2} \\ = π \times 12.25\end{matrix} \qquad equation 4$$

where the radius r is, for example, 3.5 μm. The cross-sectional area of the same aperture at the depth d is expressed by equation 5:

$$\begin{matrix}S = π \times {( r + d )}^{2} \\ = π \times ( {r}^{2} + 2 r \times d + {d}^{2} ) \\ = π \times ( 12.25 + 7 d + {d}^{2} )\end{matrix} \qquad equation 5$$

As can be seen from equations 2 and 4, the cross-sectional areas of an aperture having an elliptical shape and an aperture having a perfect circular shape at a depth of 0 are equal. On the other hand, the cross-sectional area calculated from equation 3 is larger than the cross-sectional area calculated from equation 5. That is, if the aperture 21b has an aspect ratio of greater than 1:1, the cross-sectional area of the heat path 60 increases, and accordingly, the thermal resistance decreases, thus improving the heat dissipation performance.

Next, the results in FIGS. 6B and 6C are described. The surface-emitting laser 100 is placed in an environment at 90° C. and is supplied with power at 8 mA and 2.1 V. The heat path 60 is shaped as shown in FIG. 7.

In FIG. 6B, the horizontal axis represents the aspect ratio of the aperture 21b, whereas the vertical axis represents the normalized thermal resistance of the surface-emitting laser 100. As shown in FIG. 6B, the thermal resistance decreases as the aspect ratio becomes larger. As compared to an aspect ratio of 1:1, the thermal resistance decreases by about 10% at an aspect ratio of 5:1 and decreases by about 20% at an aspect ratio of 10:1.

In FIG. 6C, the horizontal axis represents the aspect ratio of the aperture 21b, whereas the vertical axis represents the normalized life of the surface-emitting laser 100. As shown in FIG. 6C, the life becomes longer as the aspect ratio becomes larger. As compared to an aspect ratio of 1:1, the life is about twice as long at an aspect ratio of and is about 3.5 times as long at an aspect ratio of 10:1.

In the first embodiment, the length 2ra of the major axis a of the aperture 21b is twice or more the length 2rb of the minor axis b of the aperture 21b. That is, the aspect ratio of the aperture 21b is 2:1 or more. Thus, as explained using equations 2 and 3, the cross-sectional area of the heat path 60 becomes larger in the depth direction. Accordingly, as shown in FIG. 6B, the thermal resistance decreases, thus reducing the susceptibility of the surface-emitting laser 100 to thermal degradation. As a result, as shown in FIG. 6C, the life of the surface-emitting laser 100 is prolonged.

The length 2ra of the major axis a of the aperture 21b is preferably twice or more the length 2rb of the minor axis b of the aperture 21b. This increases the aspect ratio and thus, as shown in FIGS. 6B and 6C, decreases the thermal resistance and prolongs the life. On the other hand, as the aspect ratio of the aperture 21b becomes larger, the aspect ratio of laser light also becomes larger. To achieve the desired laser light, it is preferred that the length 2ra of the major axis a be ten times or less the length 2rb of the minor axis b. That is, it is preferred that the aspect ratio be 5:1 or more and 10:1 or less. As compared to the example in which the aspect ratio is 1:1, the thermal resistance can be decreased by about 10% to 20%, and the life can be prolonged by about 2 to 3.5 times. The aspect ratio may also be, for example, 1.5:1 or more, or 3:1 or more, and 8:1 or less, 9:1 or less, 11:1 or less, or 12:1 or less.

The aperture 21b is elliptical and has the major axis a and the minor axis b. Because the aspect ratio is greater than 1:1, the thermal resistance decreases, thus reducing the susceptibility to thermal degradation.

The mesa 19 has an elliptical shape with a major axis and a minor axis, and the length La of the major axis is twice or more the length Lb of the minor axis. By oxidizing a portion of the DBR layer 20 from the periphery of the mesa 19, the aperture 21b having the major axis a and the minor axis b can be formed.

Because the oxidation speed of the DBR layer 20 is dependent on plane orientation, the aperture 21b can be formed by oxidation if the directions of the major and minor axes of the mesa 19 are adjusted. The oxidation speed of the DBR layer 20 is slower in the [011] and [01-1] directions and is faster in the [001] and [010] directions. Accordingly, the mesa 19 is formed on the (100) plane of the substrate 10, and the major axis of the mesa 19 is inclined with respect to the [010] direction. Because the effect of the difference in oxidation speed is reduced, an aperture 21b having a large aspect ratio can be formed.

The major and minor axes of the mesa 19 and the aperture 21b are inclined at an angle of, for example, 35° or more and 55° or less, particularly preferably 45°, with respect to the [011] direction. That is, as shown in FIG. 2A, the major axis of the mesa 19 is oriented in the [001] direction, whereas the minor axis of the mesa 19 is oriented in the direction. In this way, the aperture 21b can be formed. The major axis a and the minor axis b are oriented in the same direction as the major and minor axes of the mesa 19.

Alternatively, as shown in FIG. 2B, the major axis may be oriented in the [010] direction, whereas the minor axis may be oriented in the [001] direction. That is, the major and minor axes are inclined at an angle of, for example, 35° or more and 55° or less with respect to the <011> direction, and are preferably oriented in the <001> direction.

The DBR layers 12 and 20 are formed of AlGaAs and thus has a higher thermal resistance than the GaAs substrate 10. On the other hand, it is important to dissipate heat from the active layer 18 sandwiched between the DBR layers 12 and 20. Because the aperture 21b in the first embodiment has an aspect ratio of 2:1 or more, the thermal resistance decreases. Thus, heat can be effectively released from the active layer 18 through the heat path 60 extending under the aperture 21b and the substrate 10, thereby reducing the susceptibility to degradation.

### Second Embodiment

FIG. 8 is a plan view showing the mesa 19 and the aperture 21b. As shown in FIG. 8, the mesa 19 is rectangular with rounded corners, and the aperture 21b is elliptical. The major axes of the mesa 19 and the aperture 21b are oriented in the [011] direction of the substrate 10, whereas the minor axes of the mesa 19 and the aperture 21b are oriented in the [01-1] direction of the substrate 10. The aperture 21b has an aspect ratio of, for example, 2:1 or more and 10:1 or less. The remaining configuration is identical to that of the first embodiment.

Because the aperture 21b in the second embodiment has an aspect ratio of 2:1 or more, as in the first embodiment, the thermal resistance decreases, thus reducing the susceptibility to thermal degradation. The major axis of the mesa 19 is oriented in the direction, whereas the minor axis of the mesa 19 is oriented in the [01-1] direction. Because of the difference in oxidation speed between the <011> and <001> directions, the elliptical aperture 21b can be formed.

The shapes of the mesa 19 and the aperture 21b are not limited to an elliptical shape and a rectangular shape with rounded corners, but may be any shape that is longer in one direction and is shorter in another direction. In other words, the mesa 19 and the aperture 21b may be of any shape having a major axis and a minor axis. The major axis is the longest straight line extending across the mesa 19 or the aperture 21b, whereas the minor axis is a straight line crossing the major axis and shorter than the major axis. The major and minor axes may or may not be orthogonal to each other.

What is claimed is:

1. A surface-emitting laser comprising:
a substrate;
a lower reflector layer disposed on the substrate;
an active layer disposed on the lower reflector layer; and
an upper reflector layer disposed on the active layer,
wherein the lower reflector layer, the active layer, and the upper reflector layer form a mesa,
the mesa has a current confinement structure,
the current confinement structure includes a current confinement layer, the current confinement layer including an oxide layer extending from a periphery of the mesa and an aperture surrounded by the oxide layer, the aperture overlapping the active layer,
the aperture has a major axis and a minor axis, and
a length of the major axis is twice or more a length of the minor axis.

2. The surface-emitting laser according to claim 1, wherein the length of the major axis of the aperture is twice or more and ten times or less the length of the minor axis of the aperture.

3. The surface-emitting laser according to claim 1, wherein the aperture is elliptical.

4. The surface-emitting laser according to claim 1, wherein
the mesa has a major axis and a minor axis, and
a length of the major axis of the mesa is twice or more a length of the minor axis of the mesa.

5. The surface-emitting laser according to claim 4, wherein
the lower reflector layer, the active layer, and the upper reflector layer are disposed on a (100) plane of the substrate, and
the major axis of the mesa is inclined with respect to a <011> direction of the substrate.

6. The surface-emitting laser according to claim 5, wherein the major axis of the mesa is inclined at an angle of 35° or more and 55° or less with respect to the <011> direction of the substrate.

7. The surface-emitting laser according to claim 1, wherein
the substrate comprises gallium arsenide;
the lower reflector layer and the upper reflector layer comprise aluminum gallium arsenide, and
the current confinement layer includes aluminum oxide.

8. A method for manufacturing a surface-emitting laser, comprising the steps of:
forming, in sequence, a lower reflector layer, an active layer, and an upper reflector layer on a substrate;
forming a mesa from the lower reflector layer, the active layer, and the upper reflector layer; and
forming a current confinement structure in the mesa,
wherein the step of forming the current confinement structure includes oxidizing a portion of the upper reflector layer from a periphery of the mesa to form an oxide layer and an aperture surrounded by the oxide layer, the aperture overlapping the active layer,
the mesa has a major axis and a minor axis,
a length of the major axis of the mesa is twice or more a length of the minor axis of the mesa, and
the lower reflector layer, the active layer, and the upper reflector layer are formed on a (100) plane of the substrate.
